(19) United States
(12) Patent Application Publication
(10) Pub. No.: US 2004/0214108 A1
(43) Pub. Date: Oct. 28, 2004

(54) Ionic liquids as dissolution inhibitors in imageable elements

(76) Inventors: Kevin B. Ray, Fort Collins, CO (US); S. Peter Pappas, Juno Beach, FL (US); John Kalamen, Loveland, CO (US)

Correspondence Address: RatnerPrestia, Nemours Building, 1007 Orange Street, Suite 1100, P.O. Box 1596, Wilmington, DE, 19899, US

(21) Appl. No.: 10/423,343

(22) Filed: Apr. 25, 2003

(51) Int. Cl. G03F 7/039; G03F 7/30; B41N 1/14

(52) U.S. Cl. 430/273.1; 430/944; 430/964; 430/302; 430/326; 430/270.1; 430/271.1; 101/463.1; 101/467

(57) ABSTRACT

Thermally imageable elements useful as lithographic printing plate precursors are disclosed. The elements comprise a top layer over a support. The top layer comprises a phenolic resin and an ionic liquid.

### FIELD OF THE INVENTION

This invention relates to thermally imageable elements. More particularly, this invention relates to imageable elements that contain ionic liquids as dissolution inhibitors.

### BACKGROUND OF THE INVENTION

In lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. Typically, the ink is first transferred to an intermediate blanket, which in turn transfers the ink to the surface of the material upon which the image is to be reproduced.

Imageable elements useful as lithographic printing plate precursors typically comprise a top layer applied over the hydrophilic surface of a substrate. The top layer typically includes one or more radiation-sensitive components, which may be dispersed in a suitable binder. Alternatively, the radiation-sensitive component can also be the binder material. If, after imaging, the imaged regions of the top layer are removed in the developing process revealing the underlying hydrophilic surface of the substrate, the precursor is positive working. Conversely, if the unimaged regions are removed by the developing process, the precursor is negative-working. In each instance, the regions of the top layer (i.e., the image areas) that remain are ink-receptive, and the regions of the hydrophilic surface revealed by the developing process accept water and aqueous solutions, typically a fountain solution, and repel ink.

Imaging of the imageable element with ultraviolet and/or visible radiation is typically carried out through a mask, which has clear and opaque regions. Imaging takes place in the regions under the clear regions of the mask but does not occur in the regions under the opaque regions of the mask. The mask is usually a photographic negative of the desired image. If corrections are needed in the final image, a new mask must be made. This is a time-consuming process. In addition, the mask may change slightly in dimension due to changes in temperature and humidity. Thus, the same mask, when used at different times or in different environments, may give different results and could cause registration problems.

Direct digital imaging of imageable elements, which obviates the need for imaging through a mask, is becoming increasingly important in the printing industry. Positive-working imageable elements for the preparation of lithographic printing plates have been developed for use with infrared lasers. Although these elements offer substantial advantages over elements exposed through masks, there is a continuing need for thermally imageable positive-working imageable elements to provide greater formulation choice.

### SUMMARY OF THE INVENTION

In one aspect, the invention is an imageable element comprising:

a) a substrate, and

b) a top layer over the substrate;

in which:

the top layer comprises a phenolic resin and a dissolution inhibitor; and

the dissolution inhibitor is an ionic liquid.

In another aspect, the invention is a method for forming an image by imaging and developing the imageable element.

### DETAILED DESCRIPTION OF THE INVENTION

Unless the context indicates otherwise, in the specification and claims, the terms ionic liquid, photothermal conversion material, phenolic resin, novolac resin, and similar terms include mixtures of such materials. Unless otherwise specified, all percentages are percentages by weight. Thermal imaging refers to imaging either with a hot body or with an infrared laser.

### Imageable Element

Positive working thermally imageable elements comprising a top layer over the surface of a substrate are known. The top layer comprises a polymeric binder and a dissolution inhibitor. Other layers that are conventional components of imageable elements may also be present. A photothermal conversion material may be present in the element. Single layer elements are disclosed in, for example, West, U.S. Pat. No. 6,090,532; Parsons, U.S. Pat. No. 6,280,899; McCullough, U.S. Pat. Pub. No. 2002/0136961; and WO99/21715, the disclosures of which are all incorporated herein by reference. Multi-layer elements are disclosed in Shimazu, U.S. Pat. No. 6,294,311, and U.S. Pat. No. 6,352,812; Patel, U.S. Pat. No. 6,352,811; and Savariar-Hauck, U.S. Pat. No. 6,358,669, and U.S. Pat. No. 6,528,228; the disclosures of which are all incorporated herein by reference.

Preferably, the binder in the top layer is a light-stable, water-insoluble, developer-soluble, film-forming phenolic resin. Phenolic resins have a multiplicity of phenolic hydroxyl groups, either on the polymer backbone or on pendent groups. Useful phenolic resins include polyvinyl compounds having phenolic hydroxyl groups, such as, polyhydroxystyrenes and copolymers containing recurring units of a hydroxystyrene, and polymers and copolymers containing recurring units of substituted hydroxystyrenes. Novolac resins, resol resins, acrylic resins that contain pendent phenol groups, and polyvinyl phenol resins are preferred phenolic resins. Novolac resins are more preferred.

Novolac resins are commercially available and are well known to those skilled in the art. They are typically prepared by the condensation reaction of a phenol, such as phenol, m-cresol, o-cresol, p-cresol, etc, with an aldehyde, such as formaldehyde, paraformaldehyde, acetaldehyde, etc. or a ketone, such as acetone, in the presence of an acid catalyst. Typical novolac resins include, for example, phenol-formaldehyde resins, cresol-formaldehyde resins, phenol-cresol-formaldehyde resins, p-t-butylphenol-formaldehyde resins, and pyrogallol-acetone resins. Particularly useful novolac resins are prepared by reacting m-cresol, mixtures of m-cresol and p-cresol, or phenol with formaldehyde using conventional conditions.

A solvent soluble novolac resin is one that is sufficiently soluble in a coating solvent to produce a coating solution that can be coated to produce a top layer. When the imageable element comprises an underlayer, the novolac resin preferably has the highest possible weight average molecular weight that maintains its solubility in common coating solvents, such as acetone, tetrahydrofuran, and 1-methoxypropan-2-ol. Top layers comprising novolac resins, including for example m-cresol only novolac resins (i.e. those that contain at least about 97 mol % m-cresol) and m-cresol/p-cresol novolac resins that have up to 10 mol % of p-cresol, having a weight average molecular weight of at least 10,000, typically at least 13,000, especially at least 15,000 and more especially at least 18,000, and even more especially 25,000, have excellent ability to withstand scuffing. Top layers comprising m-cresol/p-cresol novolac resins with at least 10 mol % p-cresol, having a weight average molecular weight of at least 8,000, especially at least 10,000, more especially at least 25,000, have excellent ability to withstand scuffing. Novolac resins prepared by solvent condensation produce top layers that have greater ability to withstand scuffing than top layers prepared from similar resins prepared by hot melt condensation.

The dissolution inhibitor is an ionic liquid or a mixture of ionic liquids. Ionic liquids are salts with melting points under 100° C. Ionic liquids with melting points less than 70° C., less than 50° C., less than 30° C., less than 20° C., and/or less than 0° C. can be used to advantage as dissolution inhibitors in the imageable elements of the invention.

Typical ionic liquids have an organic cation and an anion, which may be either organic or inorganic. Typical cations are imidazolium cations, pyridinium cations, pyrrolidinium cations, phosphonium cations, and tetralkylammonium cations. Preferred cations are imidazolium cations, such as 1,3-dimethylimidazolium, 1-ethyl-3-methylimidazolium, 1,2-dimethyl-3-propylimidazolium, 1-ethyl-2,3-dimethylimidazolium, 1-butyl-3-methylimidazolium, 1-hexyl-3-methylimidazolium, and 1-methyl-3-octylimidazolium; and pyridinium cations, such as 1-butyl-4-methylpyridinium. Typical anions are methylsulfonate, trifluoromethylsulfonate, bromide, chloride, nitrate, tetrafluoroborate, hexafluorophosphate, methylsulfate, and bromotrichloroaluminate. Hydrophobic ionic liquids are disclosed, for example, in Koch, U.S. Pat. No. 5,827,602, incorporated herein by reference. The hydrophobic ionic liquids have non-Lewis acid-containing polyatomic anions in which the van der Waals volume exceeds 100 Å³, such as bis(trifluoromethylsulfonyl)imide, bis(pentafluoroethylsulfonyl)imide, tris(trifluoromethylsulfonyl)methide, bis(pentafluoroethylsulfonyl)imide, and perfluoro-1,1-dimethylpropyl alkoxide.

Numerous ionic liquids are known to those skilled in the art. Typical ionic liquids include, for example, 1,3-dimethylimidazolium methylsulfate (DiMIM MeSO₄), 1,2-dimethyl-3-propylimidazolium tris(trifluoromethylsulfonyl)methide, 1-ethyl-3-methylimidazolium bromide, 1-ethyl-3-methylimidazolium chloride, 1-ethyl-3-methylimidazolium hexafluorophosphate, 1-ethyl-3-methylimidazolium nitrate,1-ethyl-3-methyl imidazolium tetrafluoroborate, 1-ethyl-3-methyl imidazolium trifluoromethylsulfonate, 1-ethyl-3-methylimidazolium bis(trifluoromethylsulfonyl)imide (EMI Im), 1-ethyl-3-methylimidazolium bis(pentafluoroethylsulfonyl)imide, 1-ethyl-2,3-dimethylimidazolium chloride, 1-butyl-3-methylimidazolium bromide, 1-butyl-3-methylimidazolium chloride (BMIM Cl), 1-ethyl-2,3-dimethylimidazolium tosylate (EDiMIM TOS), 1-butyl-3-methylimidazolium methylsulfate, 1 -butyl-3-methylimidazolium hexafluorophosphate (BMIM PF₆),1-butyl-3-methylimidazolium diethyleneglycolmonomethylether sulfate, N-propyl-3-methylpyridinium bis(trifluoromethylsulfonyl)imide, 1-butyl-3-methylimidazolium tetrafluoroborate (BMIM BF₄), 1-butyl-3-methylimidazolium bromotrichloroaluminate, 1-butyl-3-methylimidazolium diethyleneglycolmonomethylether sulfate (BMIM MDEGSO₄), 1-butyl-3-methylimidazoliu m phosphate, 1-butyl-3-methylimidazolium octylsulfate (BMIM OCSO₄), 1-butyl-2,3-dimethylimidazolium chloride, N-butyl-3-methylpyridinium bis(trifluoromethylsulfonyl)imide, 1-hexyl-3-methylimidazolium chloride, 1-hexyl-3-methylimidazolium hexafluorophosphate, 1-hexyl-3-methylimidazolium tetrafluoroborate, 1-hexyl-2,3-dimethylimidazolium chloride, 1-octyl-3-methylimidazolium chloride, 1-decyl-3-methylimidazolium chloride, 1-methyl-3-octylimidazolium chloride, 1-methyl-3-octylimidazolium diethyleneglycolmonomethylether sulfate (OMIM MDEGSO₄), 1-methyl-3-octylimidazolium octylsulfate (OMIM OCSO₄), 1-methyl-3-octylimidazolium tetrafluoroborate (OMIM BF₄), 1-octadecyl-3-methylimidazolium chloride, 1-butyl-4-methylpyridinium chloride, 1-butyl-4-methylpyridinium hexafluorophosphate, 1-butyl-4-methylpyridinium tetrafluoroborate, N-octyl-pyridinium tris(trifluoromethylsulfonyl)methide, N-hexyl-pyridinium tetrafluoroborate, 4-methyl-N-butyl-pyridinium chloride, N-hexyl-pyridinium bis(trifluoromethylsulfonyl)imide, 1-butyl-1-methyl-pyrrolidinium chloride, 1,1-dimethyl-pyrrolidinium tris(pentafluoroethyl)trifluorophosphate, 1-hexyl-1-methyl-pyrrolidinium dicyanamide, 1-octyl-1-methyl-pyrrolidinium chloride, tetramethyl-ammonium bis(trifluoromethyl)imide, tetrabutyl-ammonium bis(trifluoromethyl)imide, tetraethyl-ammonium tris(pentafluoroethyl)trifluorophosphate, and tetrabutyl-phosphonium tris(pentafluoroethyl)trifluorophosphate.

The dissolution inhibitor comprises typically about 0.1 wt % to about 15 wt %, preferably about 0.5 wt % to about 10 wt %, more preferably about 1 wt % to 5 wt %, of the top layer, based on the dry weight of the top layer.

When present, the underlayer is between the hydrophilic surface of the substrate and the top layer. After imaging, it is removed by the developer in the imaged regions to reveal the underlying hydrophilic surface of the substrate. The polymeric material in the underlayer is preferably soluble in the developer to prevent sludging of the developer. In addition, it is preferably insoluble in the solvent used to coat the top layer so that the top layer can be coated over the underlayer without dissolving the underlayer.

Polymeric materials useful in the underlayer include those that contain an acid and/or phenolic functionality, and mixtures of such materials. Useful polymeric materials include carboxy functional acrylics, vinyl acetate/crotonate/vinyl neodecanoate copolymers, styrene maleic anhydride copolymers, phenolic resins, maleated wood rosin, and combinations thereof. Underlayers that provide resistance both to fountain solution and aggressive washes are disclosed in Shimazu, U.S. Pat. No. 6,294,311, incorporated herein by reference.

Particularly useful polymeric materials for the underlayer are copolymers of N-phenylmaleimide, methacrylamide, and methacrylic acid, more preferably those that contain about 25 to about 75 mol %, preferably about 35 to about 60 mol % of N-phenylmaleimide; about 10 to about 50 mol %, preferably about 15 to about 40 mol % of methacrylamide; and about 5 to about 30 mol %, preferably about 10 to about 30 mol %, of methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid.

These polymeric materials are soluble in a methyl lactate/methanol/-dioxolane (15:42.5:42.5 wt %) mixture, which can be used as the coating solvent for the underlayer. However, they are poorly soluble in solvents such as acetone and toluene, which can be used as solvents to coat the top layer on top of the underlayer without dissolving the underlayer.

Other useful polymeric materials include those that comprise a monomer that has a urea bond in its side chain (i.e., a pendent urea group), such as are disclosed in Ishizuka, U.S. Pat. No. 5,731,127. These copolymers comprise about 10 to 80 wt %, preferably about 20 to 80 wt %, of one or more monomers represented by the general formula:

CH₂═C(R)—CO₂—X—NH—CO—NH—Y-Z,

in which R is —H or —CH₃; X is a bivalent linking group; Y is a substituted or unsubstituted bivalent aromatic group; and Z is —OH, —COOH, or —SO₂NH₂.

A useful monomer is:

CH₂═C(CH₃)—CO₂—CH₂CH₂—NH—CO—NH-p-C₆H₄-Z,

in which Z is —OH, —COOH, or —SO₂NH₂, preferably —OH.

The copolymers also comprise 20 to 90 wt % other polymerizable monomers, such as maleimide, acrylic acid, methacrylic acid, acrylic esters, methacrylic esters, acrylonitrile, methacrylonitrile, acrylamides, and methacrylamides.

Another group of polymeric materials that are useful in the underlayer include copolymers that comprise about 10 to 90 mol % of a sulfonamide monomer unit, especially those that comprise N-(p-aminosulfonylphenyl)-methacrylamide, N-(m-aminosulfonylphenyl)methacrylamide, N-(o-aminosulfonylphenyl)methacrylamide, and/or the corresponding acrylamide. Useful materials that comprise a pendent sulfonamide group, their method of preparation, and monomers useful for their preparation, are disclosed in Aoshima, U.S. Pat. No. 5,141,838. Particularly useful polymeric materials comprise (1) the sulfonamide monomer unit, especially N-(p-aminosulfonylphenyl)methacrylamide; (2) acrylonitrile and/or methacrylonitrile; and (3) methyl methacrylate and/or methyl acrylate.

Combination of (1) a copolymer that comprises N-substituted maleimides, especially N-phenylmaleimide; methacrylamides, especially methacrylamide; and acrylic and/or methacrylic acid, especially methacrylic acid with (2) a copolymer that comprises a urea in its side chain or with a copolymer that comprises 10 to 90 mol % of a sulfonamide monomer unit, especially one that comprises N-(p-aminosulfonylphenyl)methacrylamide, N-(m-aminosulfonylphenyl)-methacrylamide, N-(o-aminosulfonylphenyl)methacrylamide, and/or the corresponding acrylamide, can be used. One or more other polymeric materials, such as novolac resins, may also be present in the combination. Preferred other polymeric materials, when present, are novolac resins.

Imageable elements that are to be imaged with infrared radiation typically comprise an infrared absorber, known as a photothermal conversion material. Photothermal conversion materials absorb radiation and convert it to heat. Although a photothermal conversion material is not necessary for imaging with a hot body, imageable elements that contain a photothermal conversion material may also be imaged with a hot body, such as a thermal head or an array of thermal heads. In thermally imageable elements that do not comprise an underlayer, the photothermal conversion material may be in the top layer and/or in a separate absorber layer between the top layer and the substrate. In elements that also comprise an underlayer, the photothermal conversion material may be in the top layer, and/or in the underlayer, and/or in a separate absorber layer between the top layer and the underlayer. To minimize ablation of the top layer during imaging with an infrared laser, the photothermal conversion material is preferably in the underlayer and/or a separate absorber layer, and the top layer is substantially free of the photothermal conversion material. To prevent sludging of the developer by insoluble material, photothermal conversion materials that are soluble in the developer are preferred.

The photothermal conversion material may be, for example, an indoaniline dye, an oxonol dye, a porphyrin derivative, an anthraquinone dye, a merostyryl dye, a pyrylium compound, or a squarylium derivative with the appropriate absorption spectrum and solubility. Dyes, especially dyes with a high extinction coefficient in the range of 750 nm to 1200 nm, are preferred. Absorbing dyes are disclosed in numerous publications, for example, Nagasaka, EP 0,823,327; DeBoer, U.S. Pat. No. 4,973,572; Jandrue, U.S. Pat. No. 5,244,771; and Chapman, U.S. Pat. No. 5,401,618. Examples of useful cyanine dyes include: 2-[2-[2-phenylsulfonyl-3-[2-(1,3-dihydro-1,3,3-trimethyl-2H-indol-2-ylidene)-ethylidene]-1-cyclohexen-1-yl]-ethenyl]-1,3,3-trimethyl-3H-indolium chloride; 2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indolium chloride; 2-[2-[2-thiophenyl-3-[2-(1,3-dihydro-1,3,3-trimethyl-2H-indol-2-ylidene)-ethylidene]-1-cyclopenten-1-yl]-ethenyl]-1,3,3-trimethyl-3H-indolium tosylate; 2-[2-[2-chloro-3-[2-ethyl-(3H-benzthiazole-2-ylidene)-ethylidene]-1-cyclohexen-1-yl]-ethenyl]-3-ethyl-benzthiazolium tosylate; and 2-[2-[2-chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium tosylate. Other examples of useful absorbing dyes include: ADS-830A and ADS-1064 (American Dye Source, Montreal, Canada), EC2117 (FEW, Wolfen, Germany), Cyasorb IR 99 and Cyasorb IR 165 (Glendale Protective Technology), Epolite IV-62B and Epolite III-178 (Epoline), PINA-780 (Allied Signal), SpectraIR 830A and SpectralR 840A (Spectra Colors), as well as IR Dye A, and IR Dye B, whose structures are shown below.

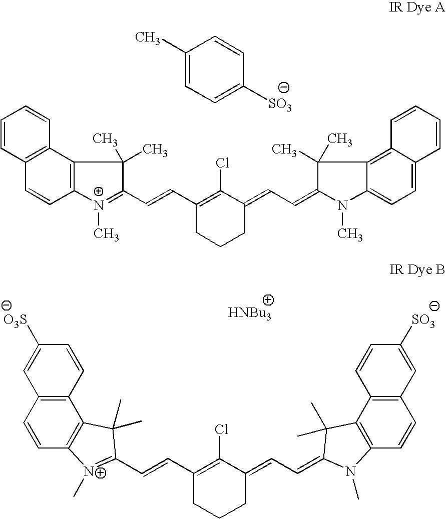

Other useful photothermal conversion materials include infrared absorbers of Structure I, Structure II, and Structure III. These photothermal conversion materials absorb in two different regions of the infrared spectrum so elements that comprise these materials can be imaged with imaging devices that contain lasers that emit either at about 830 nm, at about 1056 nm, or at about 1064 nm.

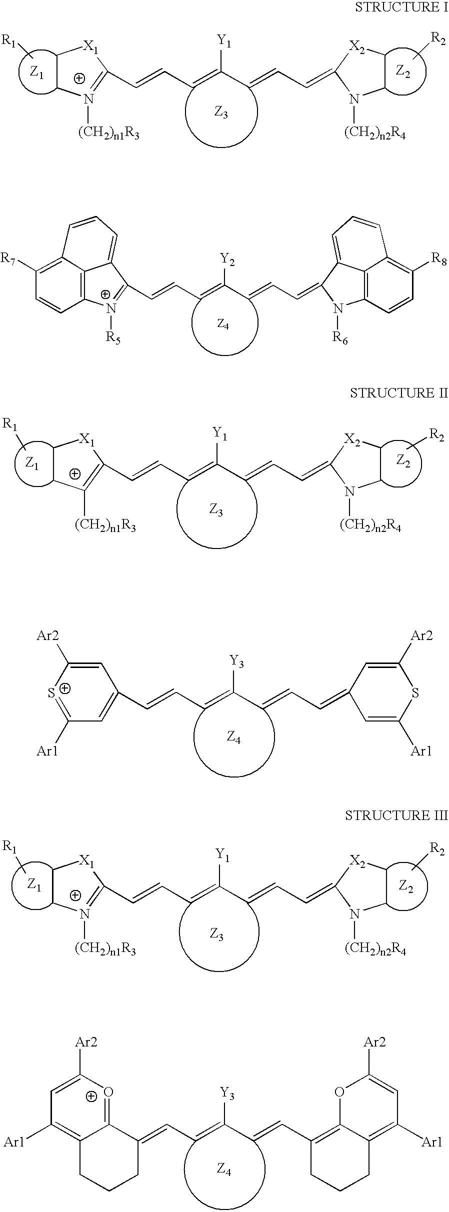

in which:

Y₁, Y₂, and Y₃ are each independently hydrogen, halo, alkyl, phenyl, substituted phenyl, phenylamino, diphenylamino, or phenylthio, preferably phenyl, hydrogen, chloro, phenylthio, or diphenylamino;

R₁, R₂, R₃, and R₄ are each independently hydrogen, alkyl, preferably methyl or ethyl, or SO₃⁻, with the proviso that two of R₁, R₂, R₃, and R₄ are SO₃⁻;

R₅ and R₆ are each independently alkyl, aryl, aralkyl, hydroxyalkyl, alkoxyalkyl, aminoalkyl, carboxyalkyl, or sulfoalkyl;

R₇ and R₈ are each independently hydrogen, alkyl, preferably alkyl of one to four carbon atoms, or halo, preferably chloro;

Ar₁ and Ar₂ are each independently phenyl or substituted phenyl, preferably phenyl;

Z₁, and Z₂ are each independently a benzo group or a naphtho group;

Z₃ and Z₄ are each independently two hydrogen atoms, a cyclohexene residue, or a cyclopentene residue;

X₁ and X₂ are each independently S, O, NH, CH₂, or, preferably, C(CH₃)₂; and

n₁ and n₂ are each independently 0 to 4, preferably 1 to 4.

Infrared absorbers of Structure I, Structure II, or Structure III may be prepared by mixing a solution of a salt that contains the desired cation with a solution of a salt that contains the desired anion and filtering off the resulting precipitate. The anion of the salt that contains the desired cation is typically, for example, a sulfate, bisulfate, or halide, such as chloride or bromide. The cation of the salt that contains the desired anion is typically ammonium, substituted ammonium such as trimethyl ammonium or tri-n-butyl ammonium, lithium, sodium, or potassium. The solvent may be water or a solvent including a mixture of water and a hydrophilic solvent such an as alcohol, for example methanol, ethanol, or propylene glycol methyl ether.

The amount of infrared absorber in the imageable composition is generally sufficient to provide an optical density of at least 0.05, and preferably, an optical density of from about 0.5 to at least about 2 to 3 at the imaging wavelength. As is well known to those skilled in the art, the amount of compound required to produce a particular optical density can be determined from the thickness of the underlayer and the extinction coefficient of the infrared absorber at the wavelength used for imaging using Beers law. The imageable composition typically comprises about 0.1 to 20% by weight, more preferably about 0.5 to 10% by weight, of the infrared absorber based on the total weight of the composition.

When an absorber layer is present, it is between the top layer and the substrate. When an underlayer is also present, the absorber layer is between the top layer and the underlayer. The absorber layer preferably consists essentially of the infrared absorber and, optionally, a surfactant. It may be possible to use less of the infrared absorber if it is present in a separate absorber layer rather than either the underlayer and/or the top layer. When an absorber layer is present, the top layer is preferably substantially free of infrared absorber, i.e. the top layer preferably does not absorb radiation used for imaging, typically radiation in the range of 800 nm to 1200 nm. The absorber layer preferably has a thickness sufficient to absorb at least 90%, preferably at least 99%, of the imaging radiation. Typically, the absorber layer has a coating weight of about 0.02 g/m² to about 2 g/m ², preferably about 0.05 g/m² to about 1.5 g/m².

To minimize migration of the photothermal conversion material from the underlayer to the top layer during manufacture and storage of the imageable element, the element may comprise a barrier layer between the underlayer and the top layer. The barrier layer comprises a polymeric material that is soluble in the developer. If this polymeric material is different from the polymeric material in the underlayer, it is preferably soluble in at least one organic solvent in which the polymeric material in the underlayer is insoluble. A preferred polymeric material for the barrier layer is polyvinyl alcohol. When the polymeric material in the barrier layer is different from the polymeric material in the underlayer, the barrier layer should be less than about one-fifth as thick as the underlayer, preferably less than a tenth of the thickness of the underlayer.

The developer penetrates and removes the imaged regions of the top layer and the underlying layer or layers, if any, without substantially affecting the complimentary unimaged regions. While not being bound by any theory or explanation, it is believed that image discrimination is based on a kinetic effect. The imaged regions of the top layer are removed more rapidly in the developer than the unimaged regions. Development is carried out for a long enough time to remove the imaged regions of the top layer and, if present, the underlying regions of the other layer or layers of the element, but not long enough to remove the unimaged regions of the top layer. Hence, the top layer is described as being “not removable” by, or “insoluble” in, the developer prior to imaging, and the imaged regions are described as being “soluble” in, or “removable” by, the developer because they are removed, and dissolved and/or dispersed, more rapidly in the developer than the unimaged regions. Typically, the underlayer, if present, is dissolved in the developer and the top layer is dissolved and/or dispersed in the developer.

The imageable composition may also comprise other ingredients such as dyes and surfactants that are conventional ingredients of imageable compositions. Surfactants may be present in the imageable composition as, for example, coating aids. A dye may be present to aid in the visual inspection of the imaged and/or developed element. Printout dyes distinguish the imaged regions from the unimaged regions during processing. Contrast dyes distinguish the unimaged regions from the imaged regions in the developed imageable element. Preferably, the dye does not absorb the imaging radiation.

The imageable composition may be coated over a variety of substrates. The particular substrate will generally be determined by the intended application. For lithographic printing, the substrate comprises a support, which may be any material conventionally used to prepare imageable elements useful as lithographic printing plates. The support is preferably strong, stable and flexible. It should resist dimensional change under conditions of use so that color records will register in a full-color image. Typically, it can be any self-supporting material, including, for example, polymeric films such as polyethylene terephthalate film, ceramics, metals, or stiff papers, or a lamination of any of these materials. Metal supports include aluminum, zinc, titanium, and alloys thereof.

Typically, polymeric films contain a sub-coating on one or both surfaces to modify the surface characteristics to enhance the hydrophilicity of the surface, to improve adhesion to subsequent layers, to improve planarity of paper substrates, and the like. The nature of this layer or layers depends upon the substrate and the composition of subsequent coated layers. Examples of subbing layer materials are adhesion-promoting materials, such as alkoxysilanes, aminopropyltriethoxysilane, glycidoxypropyltriethoxysilane and epoxy functional polymers, as well as conventional subbing materials used on polyester bases in photographic films.

The surface of an aluminum support may be treated by techniques known in the art, including physical graining, electrochemical graining, chemical graining, and anodizing. The substrate should be of sufficient thickness to sustain the wear from printing and be thin enough to wrap around a printing form, typically about 100 μm to about 600 μm. Typically, the substrate comprises an interlayer between the aluminum support and the layer of imageable composition. The interlayer may be formed by treatment of the support with, for example, silicate, dextrine, hexafluorosilicic acid, phosphate/fluoride, polyvinyl phosphonic acid (PVPA) or vinyl phosphonic acid copolymers.

The back side of the substrate (i.e., the side opposite the underlayer and layer of imageable composition) may be coated with an antistatic agent and/or a slipping layer or matte layer to improve handling and “feel” of the imageable element. Typically, the top layer has a coating weight of about 0.5 to about 4 g/m², preferably 0.8 to 3 g/m².

### Preparation of the Imageable Elements

The imageable element may be prepared by sequentially applying the underlayer over the hydrophilic surface of the substrate; applying the absorber layer or the barrier layer if present, over the underlayer; and then applying the top layer using conventional techniques.

The terms “solvent” and “coating solvent” include mixtures of solvents. These terms are used although some or all of the materials may be suspended or dispersed in the solvent rather than in solution. Selection of coating solvents depends on the nature of the components present in the various layers.

The underlayer may be applied by any conventional method, such as coating or lamination. Typically the ingredients are dispersed or dissolved in a suitable coating solvent, and the resulting mixture coated by conventional methods, such as spin coating, bar coating, gravure coating, die coating, or roller coating.

The top layer is applied to the substrate or, if present, over the underlayer. If an underlayer is present, to prevent these layers from dissolving and mixing, the top layer should be coated from a solvent in which the underlayer layer is essentially insoluble. Thus, the coating solvent for the top layer should be a solvent in which the components of the top layer are sufficiently soluble that the top layer can be formed and in which any underlying layers are essentially insoluble. Typically, the solvents used to coat the underlying layers are more polar than the solvent used to coat the top layer. An intermediate drying step, i.e., drying the underlayer, if present, to remove coating solvent before coating the top layer over it, may also be used to prevent mixing of the layers. In has been found that, the top layer is typically more resistant to attack by developers if the element is allowed to stand at room temperature for several days after coating.

Alternatively, the underlayer, the top layer or both layers may be applied by conventional extrusion coating methods from a melt mixture of layer components. Typically, such a melt mixture contains no volatile organic solvents.

### Imaging and Processing

The element may be thermally imaged with a laser or an array of lasers emitting modulated near infrared or infrared radiation in a wavelength region that is absorbed by the imageable element. Infrared radiation, especially infrared radiation in the range of about 800 nm to about 1200 nm, is typically used for imaging. Imaging is conveniently carried out with a laser emitting at about 830 nm, about 1056 nm, or about 1064 nm. Suitable commercially available imaging devices include image setters such as the Creo Trendsetter (CREO, Burnaby, British Columbia, Canada), the Screen PlateRite model 4300 and model 8600 (Screen, Rolling Meadows, Chicago, Ill., USA), and the Gerber Crescent 42T (Gerber).

Alternatively, the imageable element may be thermally imaged using a hot body, such as a conventional apparatus containing a thermal printing head. A suitable apparatus includes at least one thermal head but would usually include a thermal head array, such as a TDK Model No. LV5416 used in thermal fax machines and sublimation printers or the GS618-400 thermal plotter (Oyo Instruments, Houston, Tex., USA).

Imaging produces an imaged element, which comprises a latent image of imaged regions and complementary unimaged regions. Development of the imaged element to form a printing plate, or printing form, converts the latent image to an image by removing the imaged regions, revealing the hydrophilic surface of the underlying substrate.

The developer may be any liquid or solution that can penetrate and remove the unwanted regions of the imageable without substantially affecting the complementary regions. Suitable developers depend on the solubility characteristics of the ingredients present in the imageable element.

High pH developers can be used for both single layer and multi-layer positive working imageable elements. High pH developers typically have a pH of at least about 11, more typically at least about 12, even more typically from about 12 to about 14. High pH developers also typically comprise at least one alkali metal silicate, such as lithium silicate, sodium silicate, and/or potassium silicate, and are typically substantially free of organic solvents. The alkalinity can be provided by using a hydroxide or an alkali metal silicate, or a mixture. Preferred hydroxides are ammonium, sodium, lithium and, especially, potassium hydroxides. The alkali metal silicate has a SiO₂ to M₂O weight ratio of at least 0.3 (where M is the alkali metal), preferably this ratio is from 0.3 to 1.2, more preferably 0.6 to 1.1, most preferably 0.7 to 1.0. The amount of alkali metal silicate in the developer is at least 20 g SiO₂ per 100 g of composition and preferably from 20 to 80 g, most preferably it is from 40 to 65 g. High pH developers can be used in an immersion processor. Typical high pH developers include PC9000, PC3000, Goldstar™, Greenstar™, ThermalPro™, PROTHERM®, MX 1813, and MX1710, aqueous alkaline developers, all available from Kodak Polychrome Graphics LLC.

Multi-layer positive working imageable elements can also be developed using a solvent based developer in an immersion processor or a spray on processor. Solvent based alkaline developers comprise an organic solvent or a mixture of organic solvents and are typically silicate free. The developer is a single phase. Consequently, the organic solvent or mixture of organic solvents must be either miscible with water or sufficiently soluble in the developer that phase separation does not occur. The following solvents and mixtures thereof are suitable for use in the developer: the reaction products of phenol with ethylene oxide and propylene oxide, such as ethylene glycol phenyl ether (phenoxyethanol); benzyl alcohol; esters of ethylene glycol and of propylene glycol with acids having six or fewer carbon atoms, and ethers of ethylene glycol, diethylene glycol, and of propylene glycol with alkyl groups having six or fewer carbon atoms, such as 2-ethoxyethanol and 2-butoxyethanol. A single organic solvent or a mixture of organic solvents can be used. The organic solvent is typically present in the developer at a concentration of between about 0.5 wt % to about 15 wt %, based on the weight of the developer, preferably between about 3 wt % and about 5 wt %, based on the weight of the developer. Typical commercially available solvent based developers include 956 Developer, 955 Developer and SP200 available from Kodak Polychrome Graphics, Norwalk, Conn., USA.

Commercially available spray on processors include the 85 NS (Kodak Polychrome Graphics). Commercially available immersion processors include the Mercury Mark V processor (Kodak Polychrome Graphics, Norwalk, Conn., USA); the Global Graphics Titanium processor (Global Graphics, Trenton, N.J., USA); and the Glunz and Jensen Quartz 85 processor (Glunz and Jensen, Elkwood, Va., USA).

Following development, the printing plate is rinsed with water and dried. Drying may be conveniently carried out by infrared radiators or with hot air. After drying, the printing plate may be treated with a gumming solution comprising one or more water-soluble polymers, for example polyvinylalcohol, polymethacrylic acid, polymethacrylamide, polyhydroxyethylmethacrylate, polyvinylmethylether, gelatin, and polysaccharide such as dextrine, pullulan, cellulose, gum arabic, and alginic acid. A preferred material is gum arabic.

A developed and gummed plate may also be baked to increase the run length of the plate. Baking can be carried out, for example at about 220° C. to about 240° C. for about 7 to 10 minutes, or at a temperature of about 120° C. for about 30 min.

### Industrial Applicability

The imageable elements are useful in photomask lithography, imprint lithography, microelectronic and microoptical devices, photoresists for the preparation of printed circuit boards, and especially as lithographic printing plate precursors. Once a lithographic printing plate precursor has been imaged and developed to form a lithographic printing plate or printing form, printing can then be carried out by applying a fountain solution and then lithographic ink to the image on its surface. The fountain solution is taken up by the unimaged regions, i.e., the surface of the hydrophilic substrate revealed by the imaging and development process, and the ink is taken up by the imaged regions, i.e., the regions of the layer of imageable composition not removed by the development process. The ink is then transferred to a suitable receiving material (such as cloth, paper, metal, glass or plastic) either directly or indirectly using an offset printing blanket to provide a desired impression of the image thereon.

The advantageous properties of this invention can be observed by reference to the following examples, which illustrate but do not limit the invention.

### EXAMPLES

In the Examples, “coating solution” refers to the mixture of solvent or solvents and additives coated, even though some of the additives may be in suspension rather than in solution. Except where indicated, the indicated percentages are percentages by weight based on the total solids in the coating solution.

Glossary

| | |
|---|---|
| Aluminum Substrate A | 0.3 Gauge, aluminum sheet that had been |
| | electrograined, anodized and treated with an aqueous solution of |
| | an inorganic phosphate |
| BMIM BF₄ | 1-Butyl-3-methylimidazolium tetrafluoroborate (Strem, |
| | Newburyport, MA, USA) (mp −75° C.) |
| BMIM Cl | 1-Butyl-3-methylimidazolium chloride (Strem |
| | Chemicals, Newburyport, MA, USA) (mp 65° C.) |
| BMIM MDEGSO₄ | 1-Butyl-3-methylimidazolium |
| | diethyleneglycolmonomethylether sulfate (Strem, |
| | Newburyport, MA, USA) |
| BMIM OcSO₄ | 1-Butyl-3-methylimidazolium octylsulfate (Strem, |
| | Newburyport, MA, USA) |
| BMIM PF₆ | 1-Butyl-3-methylimidazolium hexafluorophosphate |
| | (Sachem, Austin, TX, USA) |
| Crystal Violet | C.I. 42555, Basic Violet 3; lambdaₘₐₓ = 588 nm |
| | [(p-(CH₃)₂C₆H₄)₃⁺ Cl⁻] |
| DiMIM MeSO₄ | 1,3-Dimethylimidazolium methylsulfate (Strem |
| | Chemicals, Newburyport, MA, USA) |
| EMI Im | 1-Ethyl-3-methylimidazolium |
| | bis(trifluoromethylsulfonyl)imide (Strem, Newburyport, |
| | MA, USA) |
| EDiMIM TOS | 1-Ethyl-2,3-dimethylimidazolium tosylate (Strem, |
| | Newburyport, MA, USA) |
| Goldstar ™ Developer | Sodium metasilicate based aqueous alkaline |
| | developer (Kodak Polychrome Graphics, Norwalk, |
| | CT, USA) |
| Interleaving | Polythene coated paper No. 22; 6 g/m² (Thilmany, |
| | Kaukauna, WI, USA) |
| Kraft paper | Unbleached, unglazed Kraft 90 g/m², coated with |
| | matte black low density polythene 20 g/m² (Thilmany, |
| | Kaukauna, WI, USA) |
| KF654B | 2-[2-[2-Chloro-3-[(1,3-dihydro-1,3,3-trimethyl-2H- |
| | indol-2-ylidene)ethylidene]-1-cyclohexen-1-yl]ethenyl]- |
| | 1,3,3-trimethyl-3H-Indolium bromide (Honeywell |
| | Specialty Chemicals, Morristown, NJ, USA) |
| LB-6564 | Phenol/cresol novolac resin (Bakelite AG, |
| | Southampton, UK.) |
| LB-744 | Phenol/cresol novolac resin (Bakelite AG, |
| | Southampton, UK.) |
| OMIM BF₄ | 1-Methyl-3-octylimidazolium tetrafluoroborate (Strem, |
| | Newburyport, MA, USA) (mp −88° C.) |
| OMIM MDEGSO₄ | 1-Methyl-3-octylimidazolium |
| | diethyleneglycolmonomethylether sulfate (Strem, |
| | Newburyport, MA, USA) |
| OMIM OcSO₄ | 1-Methyl-3-octylimidazolium octylsulfate (Strem, |
| | Newburyport, MA, USA) |
| SD140A | Novolac resin; 75% m-cresol/25% p-cresol; MW 1,000 |
| | (Borden Chemical, Louisville, KY, USA) |
| SD494 | Novolac resin (Borden Chemical, Columbus, OH, |
| | USA) |
| SILIKOPHEN ® P50X | Phenylmethyl polysiloxane resin (Tego Chemie |
| | Service, Essen, Germany) |

### Standard Procedures

Drop Test. A large drop of developer is placed on the top layer of an imageable element at 22° C. and the time required for the developer to remove the top layer is measured.

Image Density. Image densities were measured using a Gretag D19C Densitometer (Colour Data Systems Limited, The Wirral, UK).

Imaging. Imaging was carried out with a Creo Trendsetter 3230, a commercially available platesetter, using Procom Plus software, operating at a wavelength of 830 nm (Creo Products, Burnaby, BC, Canada).

### Examples 1-8

Coating solutions were prepared by dissolving the materials listed in Table 1 in 1-methoxypropan-2-ol. Using a wire wound bar, each coating solution was coated onto aluminum substrate A. The resulting imageable elements were dried at 100° C. for 90 seconds in a Mathis Labdryer LTE Oven (Werner Mathis, Switzerland.). The coating weight of each top layer was 1.5 g/m².

TABLE 1

| | Example # | | | | | | | |
|---|---|---|---|---|---|---|---|---|
| | 1 | 2 | 3 | 4 | 5 | 6 | 7 | 8 |
| Component | Parts by Weight | | | | | | | |
| SD140A | 100 | 98 | | | | | | |
| SD494 | | | 100 | 98 | | | | |
| LB744 | | | | | 100 | 98 | | |
| LB6564 | | | | | | | 100 | 98 |
| BMIM PF₆ | | 2 | | 2 | | 2 | | 2 |

Each imageable element was evaluated by the drop test using Goldstar™ Developer at various times after coating. The results are shown in Table 2.

TABLE 2

| | Time period between coating | | |
|---|---|---|---|
| | the imageable elements and | | |
| | completion of the drop test | | |
| | 24 hours | 48 hours | 144 hours |
| Example | Time to remove the top layer (sec) | | |
| 1 | <30 | <30 | <30 |
| 2 | 30 | 90 | 90 |
| 3 | <30 | 90 | 90 |
| 4 | 30 | 300 | 300 |
| 5 | 60 | 90 | 90 |
| 6 | 120 | 180 | 180 |
| 7 | <30 | <30 | <30 |
| 8 | 30 | 30 | <30 |

### Examples 9-11

Imageable elements were prepared as described in Examples 1-8 except that the materials shown in Table 3 were used in the coating solution. The coating weight of each top layer was 2.0 g/m².

TABLE 3

| | Example | | |
|---|---|---|---|
| | 9 | 10 | 11 |
| | Parts by | | |
| Component | Weight | | |
| LB6564 | 70 | 68 | 73 |
| LB744 | 20 | 20 | 23 |
| Crystal Violet | 2 | 2 | 2 |
| KF654B | 2 | 2 | 2 |
| SILIKOPHEN ® P50X | 6 | 6 | — |
| BMIM PF₆ | — | 2 | — |

One set of imageable elements was imaged with a 50% screen test pattern using the Creo trendsetter at imaging energy densities of 147, 161, 183, 199, 225, 260 and 307 mJ/cm². The imaged imageable elements were developed in Mercury Mark V Processor (immersion processor, Kodak Polychrome Graphics, Norwalk, Conn., USA) containing Goldstar™ Developer at 23.8° C. at processing speeds of 500 and 1500 mm/min. Image density for the 50% screen images are shown in Table 4.

TABLE 4

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 9* | — | — | — | — | — | — | — | — | — | — | — | — | — | — |
| Example 10 | 55% | 53% | 54% | 53% | 54% | 53% | 52% | 53% | 50% | 51% | 50% | 52% | 50% | 53% |
| Example 11* | — | — | — | — | — | — | — | — | — | — | — | — | — | — |

*No image formed.

Another set of imageable elements was covered with interleaving, wrapped in Kraft paper and placed in an oven with a fan at 50° C. for 3 days. The resulting heat-treated imageable elements were imaged, developed and assessed as described above. Image density for the 50% screen images are shown in Table 5.

TABLE 5

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 9 | 42% | 55% | 42% | 53% | 41% | 53% | 41% | 48% | 41% | 48% | 42% | 47% | 42% | 48% |
| Example 10 | 58% | 72% | 56% | 71% | 56% | 72% | 56% | 71% | 55% | 71% | 55% | 71% | 55% | 69% |
| Example 11 | 22% | 47% | 22% | 47% | 22% | 47% | 20% | 44% | 21% | 44% | 19% | 44% | 18% | 43% |

Generally, the screen images obtained for Example 10 have a greater area than for Example 9 and especially Example 11, i.e., there is less attack by the developer on the image (non-imaged) regions. Where values of greater than 50% are observed, this suggests that the amount of additional component is too high, leading to too great an increase in the insolubility, so that all of the exposed regions cannot be removed under the development conditions used.

The procedures of Examples 10 and 11 were repeated except that the 5% of BMIM PF₆was used in the composition. When the coating solutions were coated on the substrate and dried, blotchy poor cosmetics were observed. The resulting imageable elements were imaged to produce printing plates with unacceptable surface cosmetics.

### Examples 12-26

Imageable elements were prepared as described in Examples 1-8 except that the materials shown in Table 6 were used in the coating solution. The coating weight of each top layer was 1.5 g/m².

TABLE 6

| | Example # | | | | | | | | | | | | | | |
|---|---|---|---|---|---|---|---|---|---|---|---|---|---|---|---|
| Component | 12 | 13 | 14 | 15 | 16 | 17 | 18 | 19 | 20 | 21 | 22 | 23 | 24 | 25 | 26 |
| SD140A | 100 | 98 | | | | | 98 | 98 | 98 | | | | | | |
| SD494 | | | 100 | 98 | | | | | | 98 | 98 | 98 | | | |
| LB744 | | | | | 100 | 98 | | | | | | | 98 | 98 | 98 |
| BMIM Cl | | 2 | | 2 | | 2 | | | | | | | | | |
| DiMIM MeSO₄ | | | | | | | 2 | | | 2 | | | 2 | | |
| EdiMIM TOS | | | | | | | | 2 | | | 2 | | | 2 | |
| EMIIm | | | | | | | | | 2 | | | 2 | | | 2 |

Each imageable element was evaluated by the drop test using Goldstar™ developer at various times after coating. The results are shown in Table 7.

TABLE 7

Time period
between coating
and completion
of the drop test

| | |
|---|---|
| 24 hours | 144 hours |

| | |
|---|---|
| | Time to remove |
| Example # | the top layer (sec) |

| | | |
|---|---|---|
| 12 | <30 | <30 |
| 13 | 90 | 120 |
| 14 | <30 | 90 |
| 15 | 120 | 180 |
| 16 | 60 | 90 |
| 17 | 210 | 240 |
| 18 | 30 | 60 |
| 19 | 180 | 240 |
| 20 | 120 | 150 |
| 21 | 60 | 60 |
| 22 | 120 | 150 |
| 23 | 150 | 150 |
| 24 | 90 | 120 |
| 25 | 150 | 240 |
| 26 | 210 | 210 |

### Examples 27-32

The components in Table 8 dissolved in 1-methoxypropan-2-ol were coated onto aluminum substrate A with a wire wound bar. The coating weight was 2.0 g/m². The resulting imageable elements were dried at 100° C. for 90 seconds in a Mathis labdryer oven.

TABLE 8

Example #

| | | | | | |
|---|---|---|---|---|---|
| 27 | 28 | 29 | 30 | 31 | 32 |

| | |
|---|---|
| Component | Parts by Weight |

| | | | | | | |
|---|---|---|---|---|---|---|
| LB6564 | 70 | 68 | 73 | 68 | 68 | 68 |
| LB744 | 20 | 20 | 23 | 20 | 20 | 20 |
| Crystal Violet | 2 | 2 | 2 | 2 | 2 | 2 |
| KF654B | 2 | 2 | 2 | 2 | 2 | 2 |
| SILIKOPHEN ® | 6 | 6 | — | 6 | 6 | 6 |
| P50X | | | | | | |
| BMIM CI | — | 2 | — | — | — | — |
| DiMIM MeSO₄ | — | — | — | 2 | — | — |
| EdiMIM TOS | — | — | — | — | 2 | — |
| EMI Im | — | — | — | — | — | 2 |

One set of imageable elements was imaged with a 50% screen test pattern using the Creo trendsetter at imaging energy densities of 147, 161, 183, 199, 225, 260 and 307 mJ/cm². The imaged imageable elements were developed in a Mercury Processor containing Goldstar™ developer at 23.8° C. The elements were processed at speeds of 500 and 1500 mm/min. The resulting images were measured with a Gretag D19C Densitometer. The resulting printing plates were inked up by hand. Densitometer readings of 50% screen images exposed by the Creo Trendsetter are shown in Table 9.

TABLE 9

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 27* | — | — | — | — | — | — | — | — | — | — | — | — | — | — |
| Example 28 | 30% | 49% | 30% | 47% | 29% | 47% | 29% | 46% | 25% | 45% | 25% | 45% | 25% | 45% |
| Example 29* | — | — | — | — | — | — | — | — | — | — | — | — | — | — |
| Example 30 | — | 14% | — | 14% | — | 13% | — | 13% | — | 13% | — | 12% | — | 12% |
| Example 31 | 52% | 66% | 50% | 62% | 49% | 62% | 49% | 63% | 49% | 60% | 48% | 56% | 47% | 56% |
| Example 32 | 39% | 52% | 37% | 51% | 35% | 50% | 32% | 50% | 32% | 48% | 31% | 48% | 30% | 48% |

*No image formed.

Another set of imageable elements was covered with interleaving, wrapped in Kraft paper and placed in an oven with fan at 50° C. for 3 days. The resulting heat-treated elements were imaged, developed, and assessed as described above. Densitometer readings of 50% screen images exposed by the Creo Trendsetter are shown in Table 10.

TABLE 10

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 27 | 42% | 54% | 41% | 53% | 41% | 53% | 40% | 48% | 39% | 48% | 39% | 47% | 39% | 47% |
| Example 28 | 43% | 60% | 42% | 60% | 40% | 60% | 40% | 60% | 38% | 59% | 38% | 59% | 38% | 57% |
| Example 29 | 20% | 47% | 20% | 47% | 20% | 47% | 20% | 44% | 20% | 44% | 20% | 44% | 18% | 43% |
| Example 30 | 42% | 54% | 42% | 54% | 41% | 54% | 41% | 52% | 40% | 50% | 39% | 50% | 37% | 48% |
| Example 31 | 64% | 89% | 64% | 89% | 64% | 89% | 64% | 87% | 64% | 86% | 62% | 86% | 62% | 85% |
| Example 32 | 46% | 60% | 46% | 59% | 45% | 58% | 44% | 58% | 43% | 57% | 43% | 57% | 42% | 57% |

Generally the screen images obtained for examples 28, 30, 31 and 32 have a greater area than those images obtained for example 27 and especially example 29, i.e., there is less attack by the developer on the image (non-imaged) regions. Where values of greater than 50% are recorded, this suggests that the amount of additional component is too high, leading to too great an increase in the insolubility, so that all of the exposed area cannot be removed under the development conditions used.

### Examples 33-37

The components in Table 11 were dissolved in 1-methoxypropan-2-ol and coated onto aluminum substrate A with a wire wound bar. The coating weight was 2.0 g/m². The resulting imageable elements were dried at 100° C. for 90 seconds in a Mathis Labdryer oven.

TABLE 11

| | Example # | | | | |
|---|---|---|---|---|---|
| | 33 | 34 | 35 | 36 | 37 |
| Component | Parts by Weight | | | | |
| LB6564 | 70 | 65 | 65 | 65 | 65 |
| LB744 | 20 | 20 | 20 | 20 | 20 |
| Crystal Violet | 2 | 2 | 2 | 2 | 2 |
| KF654B | 2 | 2 | 2 | 2 | 2 |
| SILIKOPHEN ® | 6 | 6 | 6 | 6 | 6 |
| P50X | | | | | |
| BMIM CI | — | 5 | — | — | — |
| DiMIM MeSO₄ | — | — | 5 | — | — |
| EdiMIM TOS | — | — | — | 5 | — |
| EMI Im | — | — | — | — | 5 |

One set of imageable elements was imaged with a 50% screen test pattern using the Creo trendsetter at imaging energy densities of 147,161,183, 199, 225, 260 and 307 mJ/cm². The imaged elements were then developed using a Mercury processor containing Goldstar™ developer at 23.8° C. The imaged imageable elements were processed at speeds of 500 and 1500 mm/min. Images produced were read using a Gretag D19C Densitometer. Finally, the resulting plates were inked up by hand. Densitometer readings of 50% screen images exposed by the Creo Trendsetter are shown in Table 12.

TABLE 12

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 33* | — | — | — | — | — | — | — | — | — | — | — | — | — | — |
| Example 34 | 29% | 54% | 29% | 54% | 29% | 53% | 29% | 52% | 28% | 51% | 28% | 51% | 28% | 50% |
| Example 35 | 13% | 54% | 13% | 54% | 12% | 53% | 12% | 52% | 11% | 51% | 11% | 51% | 11% | 50% |
| Example 36 | 66% | 92% | 65% | 91% | 62% | 91% | 60% | 90% | 58% | 90% | 58% | 89% | 57% | 88% |
| Example 37 | 51% | 60% | 51% | 60% | 50% | 60% | 49% | 58% | 49% | 58% | 46% | 57% | 45% | 57% |

*No image formed

Another set of imageable elements was covered with interleaving paper, wrapped in Kraft paper and placed in an oven with fan at 50° C. for 3 days. The resulting heat-treated elements were imaged, developed, and evaluated as described above. Densitometer readings of 50% screen images exposed by the Creo Trendsetter are shown in Table 13.

TABLE 13

| | Imaging Energy Density (mJ/cm²) | | | | | | | | | | | | | |
|---|---|---|---|---|---|---|---|---|---|---|---|---|---|---|
| | 147 | | 161 | | 183 | | 199 | | 225 | | 260 | | 307 | |
| | Processing Speed (mm/min) | | | | | | | | | | | | | |
| | 500 | 1500 | 500 | 1500 | 500 | 1500 | 500 | 1500 | 500 | 1500 | 500 | 1500 | 500 | 1500 |
| Example 33 | 42% | 55% | 41% | 53% | 41% | 53% | 41% | 48% | 39% | 48% | 39% | 47% | 39% | 48% |
| Example 34 | 45% | 67% | 45% | 67% | 44% | 66% | 43% | 65% | 43% | 65% | 43% | 65% | 43% | 65% |
| Example 35 | 48% | 59% | 48% | 58% | 47% | 58% | 47% | 58% | 47% | 58% | 47% | 58% | 47% | 58% |
| Example 36 | 72% | 96% | 72% | 95% | 72% | 94% | 71% | 94% | 71% | 93% | 70% | 93% | 70% | 93% |
| Example 37 | 49% | 75% | 49% | 75% | 48% | 74% | 48% | 74% | 48% | 74% | 48% | 74% | 48% | 74% |

The screen images obtained for examples 34, 35, 36 and 37 have a greater area than those images obtained for example 33, i.e., there is less attack by the developer on the image (non-imaged) regions. Where values of greater than 50% are recorded, this suggests that the amount of additional component is too high, leading to too great an increase in the insolubility, so that all of the exposed area cannot be removed under the development conditions used.

### Examples 38 to 58

The components in Table 14 were dissolved in 1-methoxypropan-2-ol and coated onto aluminum substrate A with a wire wound bar. The coating weight was 1.5 g/m². The resulting imageable elements were dried at 100° C. for 90 seconds in a Mathis Labdryer oven.

TABLE 14

| | Example | | | | | | |
|---|---|---|---|---|---|---|---|
| | 38 | 39 | 40 | 41 | 42 | 43 | 44 |
| Component | Parts by Weight | | | | | | |
| SD140A | 99.5 | 97.5 | | | | | 97.5 |
| BMIM MDEGSO₄ | | 2 | | 2 | | 2 | |
| BYK 307 | 0.5 | 0.5 | 0.5 | 0.5 | 0.5 | 0.5 | 0.5 |
| SD494 | | | 99.5 | 97.5 | | | |
| LB744 | | | | | 99.5 | 97.5 | |
| BMIM OcSO₄ | | | | | | | 2 |
| | Example | | | | | | |
| | 45 | 46 | 47 | 48 | 49 | 50 | 51 |
| Component | Parts by Weight | | | | | | |
| SD140A | | | 97.5 | | | 97.5 | |
| BYK 307 | 0.5 | 0.5 | 0.5 | 0.5 | 0.5 | 0.5 | 0.5 |
| SD494 | 97.5 | | | 97.5 | | | 97.5 |
| LB744 | | 97.5 | | | 97.5 | | |
| BMIM OcSO₄ | 2 | 2 | | | | | |
| BMIM BF₄ | | | 2 | 2 | 2 | | |
| OMIM MDEGSO₄ | | | | | | 2 | 2 |
| | Example | | | | | | |
| | 52 | 53 | 54 | 55 | 56 | 57 | 58 |
| Component | Parts by Weight | | | | | | |
| SD140A | | 97.5 | | | 97.5 | | |
| BYK 307 | 0.5 | 0.5 | 0.5 | 0.5 | 0.5 | 0.5 | 0.5 |
| SD494 | | | 97.5 | | | 97.5 | |
| LB744 | 97.5 | | | 97.5 | | | 97.5 |
| OMIM MDEGSO₄ | 2 | | | | | | |
| OMIM OcSO₄ | | 2 | 2 | 2 | | | |
| OMIM BF₄ | | | | | 2 | 2 | 2 |

Samples of each imageable element were evaluated by the drop test with Goldstar™ developer. Drop test results are given in Table 15.

TABLE 15

Time period
between coating
and completion
of the drop test

| Example # | 24 hours | 144 hours |
|---|---|---|
| 38 | <30 sec | <30 sec |
| 39 | 60 sec | 90 sec |
| 40 | <30 sec | 90 sec |
| 41 | 90 sec | 150 sec |
| 42 | 60 sec | 90 sec |
| 43 | 90 sec | 120 sec |
| 44 | 30 sec | 60 sec |
| 45 | 60 sec | 120 sec |
| 46 | 90 sec | 120 sec |
| 47 | 90 sec | 120 sec |
| 48 | 90 sec | 120 sec |
| 49 | 90 sec | 120 sec |
| 50 | 60 sec | 90 sec |
| 51 | 90 sec | 120 sec |
| 52 | 90 sec | 120 sec |
| 53 | 30 sec | 60 sec |
| 54 | 90 sec | 120 sec |
| 55 | 90 sec | 210 sec |
| 56 | 30 sec | 90 sec |
| 57 | 60 sec | 90 sec |
| 58 | 90 sec | 180 sec |

Having described the invention, we now claim the following and their equivalents.

What is claimed is:

1. An imageable element comprising:
a) a substrate, and
b) a top layer over the substrate;
in which:
the top layer comprises a phenolic resin and a dissolution inhibitor; and
the dissolution inhibitor is an ionic liquid.

2. The imageable element of claim 1 in which the ionic liquid has a melting point less than 20° C.

3. The imageable element of claim 1 in which the ionic liquid comprises an imidazolium cation, a pyridinium cation, a pyrrolidinium cation, a phosphonium cation, or a tetralkylammonium cation.

4. The imageable element of claim 3 in which the cation is an imidazolium cation.

5. The element of claim 1 in which the element additionally comprises an underlayer between the top layer and the substrate.

6. The element of claim 1 in which the phenolic resin is a novolac resin.

7. The imageable element of claim 6 in which the element additionally comprises a photothermal conversion material.

8. The imageable element of claim 7 in which the ionic liquid comprises an imidazolium cation, a pyridinium cation, a pyrrolidinium cation, a phosphonium cation, or a tetralkylammonium cation.

9. The imageable element of claim 8 in which the cation is an imidazolium cation.

10. The element of claim 7 in which the element additionally comprises an underlayer between the top layer and the substrate.

11. The imageable element of claim 10 in which the ionic liquid has a melting point less than 20° C.

12. The imageable element of claim 10 in which the photothermal conversion material is in the underlayer.

13. The imageable element of claim 12 in which the ionic liquid comprises an imidazolium cation, a pyridinium cation, a pyrrolidinium cation, a phosphonium cation, or a tetralkylammonium cation.

14. The imageable element of claim 13 in which the cation is an imidazolium cation.

15. The imageable element of claim 10 in which the photothermal conversion material is an absorber layer between the top layer and the underlayer.

16. The imageable element of claim 15 in which the ionic liquid comprises an imidazolium cation, a pyridinium cation, a pyrrolidinium cation, a phosphonium cation, or a tetralkylammonium cation.

17. The imageable element of claim 16 in which the cation is an imidazolium cation.

18. A method for forming an image, the method comprising the steps of:
(a) thermally imaging an imageable element and forming an imaged imageable element comprising imaged and unimaged regions in the imageable element; and
(b) developing the imaged imageable element and removing the imaged regions;
in which:
the imageable element comprises a substrate and a top layer over the substrate;
the top layer comprises a phenolic resin and a dissolution inhibitor; and
the dissolution inhibitor is an ionic liquid.

19. The method of claim 18 in which the phenolic resin is a novolac resin.

20. The method of claim 19 in which the ionic liquid comprises an imidazolium cation, a pyridinium cation, a pyrrolidinium cation, a phosphonium cation, or a tetralkylammonium cation.

21. The method of claim 20 in which the cation is an imidazolium cation.

22. The method of claim 20 in which the ionic liquid has a melting point less than 20° C.

23. The method of claim 20 in which the element additionally comprises an underlayer between the top layer and the substrate.
